(19) United States
(12) Patent Application Publication
(10) Pub. No.: US 2026/0254452 A1
(43) Pub. Date: Aug. 27, 2026

(54) MEMBRANE ASSEMBLY AND TOUCH KEYBOARD WITH SAME

(71) Applicant: Primax Electronics Ltd., Taipei (TW)

(72) Inventors: Lei-Lung Tsai, Taipei (TW); Chih-Chen Chang, Taipei (TW); Tao-Ying Chen, Taipei (TW); Chin-Pi Huang, Taipei (TW); Chun-Chieh Huang, Taipei (TW)

(21) Appl. No.: 19/097,645

(22) Filed: Apr. 1, 2025

(30) Foreign Application Priority Data
Feb. 21, 2025 (TW) 114106400

(51) Int. Cl. H03K 17/96; H01H 13/702

(52) U.S. Cl. CPC H03K 17/9622; H01H 13/702; H03K 2217/960755

(57) ABSTRACT

A touch keyboard includes a plurality of keycaps and a membrane assembly. The membrane assembly is located under the keycaps. The keycaps have respective keycap orthographic projection areas on the membrane assembly. The membrane assembly includes a first capacitor electrode layer, a second capacitor electrode layer and a spacer layer. A capacitor is formed between the first capacitor electrode layer and the second capacitor electrode layer. The first capacitor electrode layer includes a plurality of first switch areas. The second capacitor electrode layer includes a plurality of second switch areas. There is at least an overlap region between each first switch area and the corresponding second switch area in a vertical direction. The first switch area and the corresponding second switch area are separated from each other by a first gap through a spacer hole of the spacer layer.

### FIELD OF THE INVENTION

The present invention relates to a membrane assembly and a touch keyboard with the membrane assembly.

### BACKGROUND OF THE INVENTION

Nowadays, to realize various functions in the process of operating computing devices, users need to connect multiple input devices, e.g., keyboards, mice, and touchpads. Each of the above input devices has specified operating methods and functions. For example, the keyboard is used to input texts and execute shortcut key operations. In addition, the mouse is used to accurately control the cursor position, and a touchpad is used for performing gesture operations and multi-touch operations.

However, since the above input devices need to be individually connected to the computing device and occupy multiple connection interfaces, the operating complexity is increased, and the difficulty of carrying and arranging the devices is also increased.

Currently, most computing devices cannot effectively solve the problems of using multiple input devices. Users need to prepare additional external input devices when carrying or using the computing devices, which is a burden for users who often move around or need to operate the computing devices at any time.

Therefore, it is important to provide an integrated touch keyboard.

### SUMMARY OF THE INVENTION

An object of the present invention provides an integrated touch keyboard.

The other objects and advantages of the present invention will be understood from the disclosed technical features.

In accordance with an aspect of the present invention, a touch keyboard is provided. The touch keyboard includes a plurality of keycaps and a membrane assembly. The membrane assembly is located under the plurality of keycaps. The plurality of keycaps have respective keycap orthographic projection areas on the membrane assembly. The membrane assembly includes a first capacitor electrode layer, a second capacitor electrode layer and a spacer layer. The first capacitor electrode layer includes a plurality of first switch areas, and the plurality of first switch areas are included in the respective keycap orthographic projection areas. The second capacitor electrode layer includes a plurality of second switch areas, and the plurality of second switch areas are included in the respective keycap orthographic projection areas. A capacitor is formed between the first capacitor electrode layer and the second capacitor electrode layer. There is at least an overlap region between each first switch area and the corresponding second switch area in a vertical direction. The spacer layer includes a plurality of spacer holes. Each spacer hole is aligned with the overlap region between the corresponding first switch area and the corresponding second switch area in the vertical direction. Consequently, the corresponding first switch area and the corresponding second switch area are separated from each other by a first gap through the spacer hole.

In an embodiment, the membrane assembly further includes a first film layer and a second film layer, and the spacer layer is sandwiched between the first film layer and the second film layer.

In an embodiment, the first film layer has a first inner surface and a first outer surface, and the second film layer has a second inner surface and a second outer surface. The first inner surface and the first outer surface are opposed to each other. The second inner surface and the second outer surface are opposed to each other. The first inner surface faces the second inner surface.

In an embodiment, the first capacitor electrode layer is disposed on the first inner surface, and the second capacitor electrode layer is disposed on the second inner surface.

In an embodiment, the first capacitor electrode layer includes a plurality of first electrode arrays, and the second capacitor electrode layer includes a plurality of second electrode arrays. The plurality of first electrode arrays are extended along a first direction and arranged at spacing intervals in a second direction. The plurality of second electrode arrays are extended along the second direction and arranged at spacing intervals in the first direction. The first direction and the second direction are perpendicular to each other.

In an embodiment, the membrane assembly is further connected with a control module. When the overlap region between the corresponding first switch area and the corresponding second switch area of the membrane assembly is pressed, the corresponding first switch area and the corresponding second switch area are closer to each other and separated from each other by a second gap through the spacer hole. Consequently, a capacitance value of the capacitor between the corresponding first switch area and the corresponding second switch is subjected to a change, wherein the control module generates a key signal according to the change of the capacitance value, and the second gap is greater than zero.

In an embodiment, the first gap is 0.1 mm, and the second gap is 0.01 mm.

In an embodiment, each of the first switch area and the second switch area includes a switch portion and further includes an extension portion, a concave portion, a notch portion, or a combination thereof.

In an embodiment, the membrane assembly further includes a first insulation layer and a second insulation layer. The first insulation layer covers a surface of the first capacitor electrode layer. The second insulation layer covers a surface of the second capacitor electrode layer.

In an embodiment, the first insulation layer is extended to cover the first inner surface of the first film layer, and the second insulation layer is extended to cover the second inner surface of the second film layer.

In an embodiment, the touch keyboard further includes a plurality of connecting elements, a base plate and a plurality of elastic elements. The plurality of connecting elements are pivotally coupled to the respective keycaps and the base plate. The plurality of keycaps are movable relative to the base plate through the plurality of connecting elements. The base plate is located under the membrane assembly. The plurality of elastic elements are arranged between the respective keycaps and the membrane assembly. Each of the keycaps is permitted to be returned to an original position in response to an elastic restoring force of the corresponding elastic element.

In accordance with another aspect of the present invention, a membrane assembly is provided. The membrane assembly includes a first capacitor electrode layer, a second capacitor electrode layer and a spacer layer. The first capacitor electrode layer includes a plurality of first switch areas. The second capacitor electrode layer includes a plurality of second switch areas. A capacitor is formed between the first capacitor electrode layer and the second capacitor electrode layer. There is at least an overlap region between each first switch area and the corresponding second switch area in a vertical direction. The spacer layer includes a plurality of spacer holes. Each spacer hole is aligned with the overlap region between the corresponding first switch area and the corresponding second switch area in the vertical direction. Consequently, the corresponding first switch area and the corresponding second switch area are separated from each other by a first gap through the spacer hole.

In an embodiment, the membrane assembly further includes a first film layer and a second film layer, and the spacer layer is sandwiched between the first film layer and the second film layer.

In an embodiment, the first film layer has a first inner surface and a first outer surface, and the second film layer has a second inner surface and a second outer surface. The first inner surface and the first outer surface are opposed to each other. The second inner surface and the second outer surface are opposed to each other. The first inner surface faces the second inner surface.

In an embodiment, the first capacitor electrode layer is disposed on the first inner surface, and the second capacitor electrode layer is disposed on the second inner surface.

In an embodiment, the first capacitor electrode layer includes a plurality of first electrode arrays, and the second capacitor electrode layer includes a plurality of second electrode arrays. The plurality of first electrode arrays are extended along a first direction and arranged at spacing intervals in a second direction. The plurality of second electrode arrays are extended along the second direction and arranged at spacing intervals in the first direction. The first direction and the second direction are perpendicular to each other.

In an embodiment, the membrane assembly is further connected with a control module. When the overlap region between the corresponding first switch area and the corresponding second switch area of the membrane assembly is pressed, the corresponding first switch area and the corresponding second switch area are closer to each other and separated from each other by a second gap through the spacer hole. Consequently, a capacitance value of the capacitor between the corresponding first switch area and the corresponding second switch is subjected to a change, wherein the control module generates a key signal according to the change of the capacitance value, and the second gap is greater than zero.

In an embodiment, the first gap is 0.1 mm, and the second gap is 0.01 mm.

In an embodiment, each of the first switch area and the second switch area includes a switch portion and further includes an extension portion, a concave portion, a notch portion, or a combination thereof.

In an embodiment, the membrane assembly further includes a first insulation layer and a second insulation layer. The first insulation layer covers a surface of the first capacitor electrode layer. The second insulation layer covers a surface of the second capacitor electrode layer.

In an embodiment, the first insulation layer is extended to cover the first inner surface of the first film layer, and the second insulation layer is extended to cover the second inner surface of the second film layer.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating the outer appearance of a touch keyboard according to an embodiment of the present invention;

FIG. 2A is a schematic exploded view illustrating the touch keyboard according to the embodiment of the present invention and taken along a viewpoint;

FIG. 2B is a schematic exploded view illustrating the touch keyboard according to the embodiment of the present invention and taken along another viewpoint;

FIG. 3 is a schematic cross-sectional view illustrating a portion of the touch keyboard according to the embodiment of the present invention;

FIG. 4 is a schematic exploded view illustrating the membrane assembly of the touch keyboard according to the embodiment of the present invention;

FIG. 5 is a schematic top view illustrating the membrane assembly of the touch keyboard according to the embodiment of the present invention;

FIG. 6 is a schematic cross-sectional view of the structure shown in FIG. 5 and taken along the lines A-A, B-B and C-C;

FIG. 7A schematically illustrates a plurality of first electrode arrays in the membrane assembly of the touch keyboard according to the embodiment of the present invention;

FIG. 7B schematically illustrates a plurality of second electrode arrays in the membrane assembly of the touch keyboard according to the embodiment of the present invention;

FIG. 8 is a schematic functional block diagram illustrating a control mechanism of the touch keyboard according to the embodiment of the present invention; and

FIG. 9 is a schematic cross-sectional view illustrating a portion of the touch keyboard when the touch keyboard is pressed by the user.

### DETAILED DESCRIPTION OF THE PREFERRED EMBODIMENT

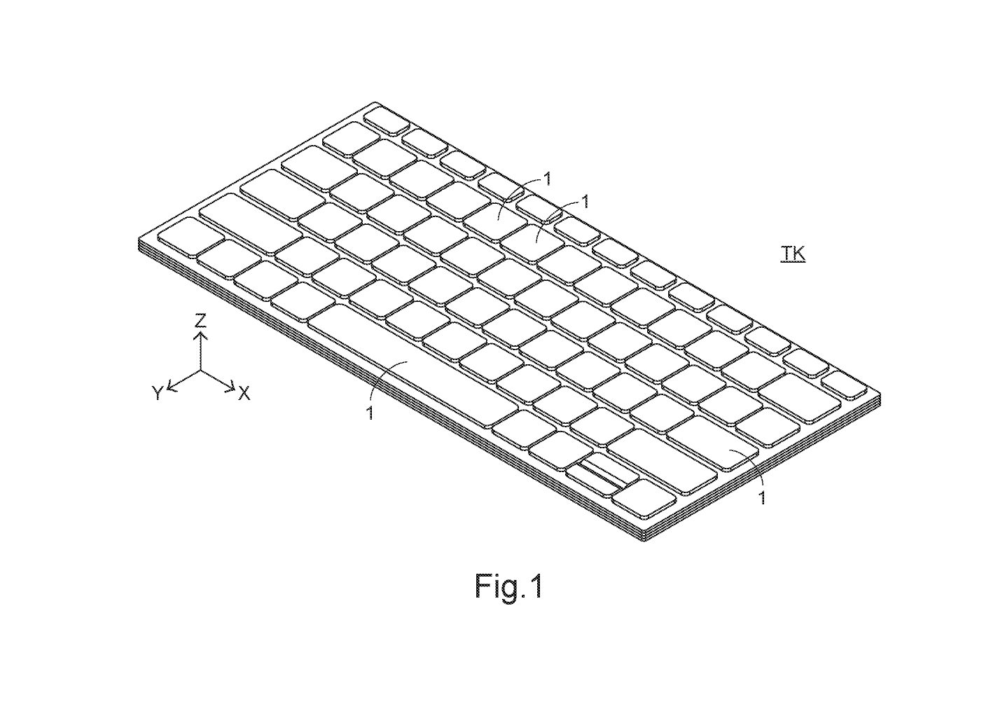

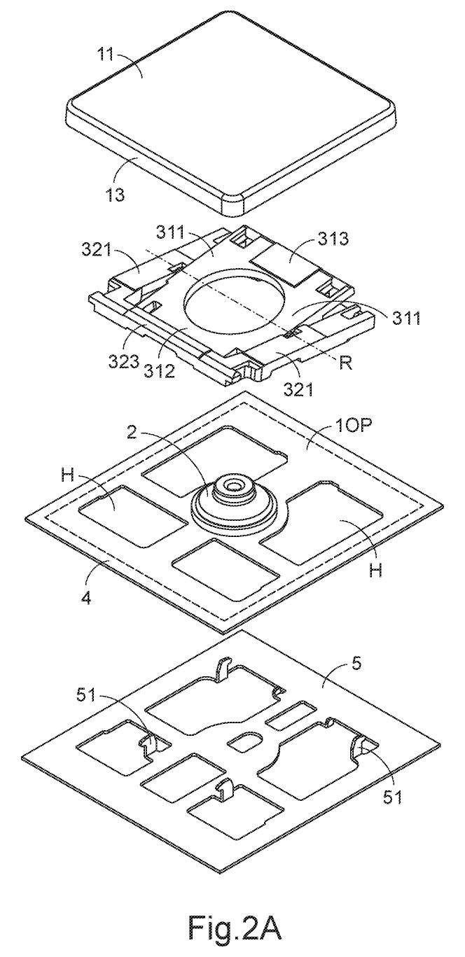

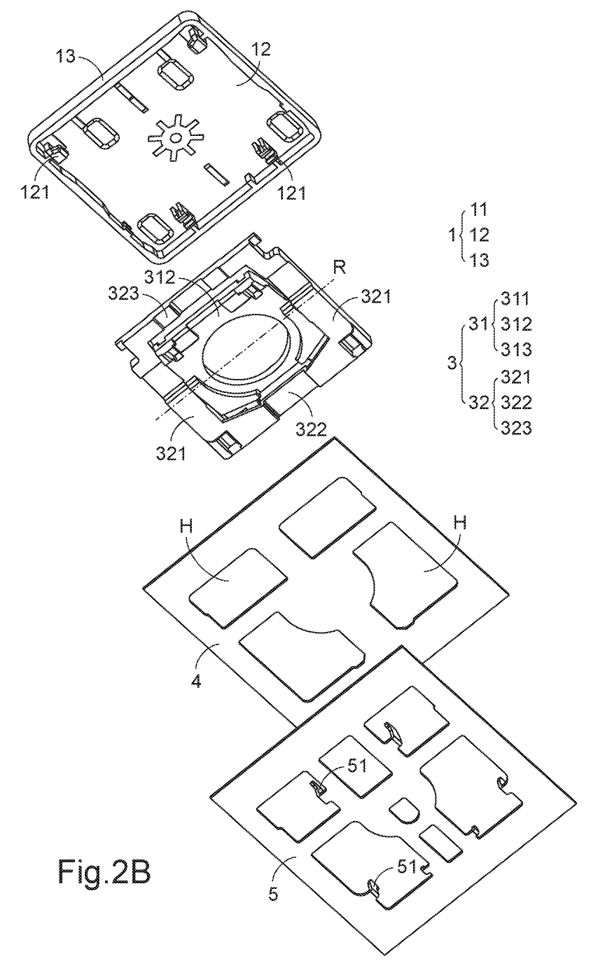

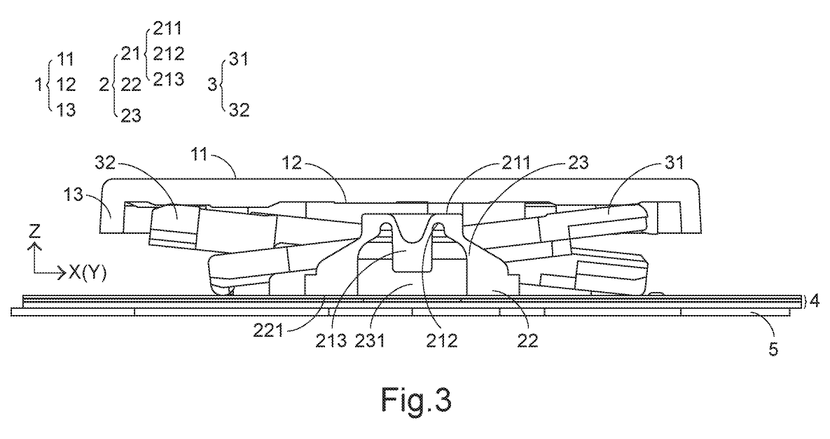

Please refer to FIGS. 1, 2A, 2B and 3. FIG. 1 is a schematic perspective view illustrating the outer appearance of a touch keyboard according to an embodiment of the present invention. FIG. 2A is a schematic exploded view illustrating the touch keyboard according to the embodiment of the present invention and taken along a viewpoint. FIG. 2B is a schematic exploded view illustrating the touch keyboard according to the embodiment of the present invention and taken along another viewpoint. FIG. 3 is a schematic cross-sectional view illustrating a portion of the touch keyboard according to the embodiment of the present invention.

The present invention provides a touch keyboard TK. From top to bottom, the touch keyboard TK includes a plurality of keycaps 1, a plurality of elastic elements 2, a plurality of connecting elements 3, a membrane assembly 4 and a base plate 5.

The plurality of keycaps 1 can be pressed down by the user. The plurality of elastic elements 2 are connected with the membrane assembly 4. The plurality of elastic elements 2 are used to provide elastic restoring forces for returning the plurality of keycaps 1. The plurality of connecting elements 3 are pivotally coupled to the respective keycaps 1 and the base plate 5. Due to the connecting elements 3, the keycaps 1 can be moved back and forth relative to the base plate 5 along the Z axis. The components of the touch keyboard TK will be described in more detail as follows.

Please refer to FIGS. 1, 2A, 2B and 3 again. The plurality of keycaps 1 can be pressed down by the user. Each keycap 1 includes a first surface 11, a second surface 12 and a cap brim 13. The first surface 11 and the second surface 12 are opposed to each other. Preferably but not exclusively, an English letter, a number, a pinyin, a punctuation mark or a function representative symbol is formed on the first surface 11 of the keycap 1. In addition, a plurality of connection structures 121 are formed on the second surface 12 of the keycap 1. That is, the plurality of connection structures 121 are protruded from the second surface 12 of the keycap 1 along the negative direction of the Z axis. In an embodiment, four connection structures 121 are formed on the second surface 12 of the keycap 1. The cap brim 13 is protruded from an edge of the first surface 11 of the keycap 1 and extended along the negative direction of the Z axis. Furthermore, each of the plurality of keycaps 1 has a keycap orthographic projection area 1OP on the membrane assembly 4. For succinctness, only one keycap orthographic projection area 1OP is shown in FIG. 2A.

Please refer to FIGS. 1, 2A, 2B and 3 again. The elastic elements 2 are made of elastic material. Preferably but not exclusively, the elastic material is rubber material. The elastic element 2 is used to provide an elastic restoring force after the keycap 1 is pressed down. In an embodiment, the elastic element 2 includes an upper portion 21, a lower portion 22 and an inclined portion 23. The upper portion 21 is located near the keycap 1. The lower portion 22 is connected with the membrane assembly 4. The inclined portion 23 is connected with the upper portion 21 and the lower portion 22. The top portion 21 includes a top surface 211, a bottom surface 212 and an actuating part 213. The top surface 211 and the bottom surface 212 are opposed to each other. The actuating part 213 is protruded from the bottom surface 212 and extended along the negative direction of the Z axis. When the membrane assembly 4 is pushed by the actuating part 213, the membrane assembly 4 is subjected to a localized deformation. In an embodiment, the actuating part 213 has a solid shape in appearance. For example, the actuating part 213 is cylindrical. The lower portion 22 includes a connection surface 221. The connection surface 221 is attached on the membrane assembly 4. The inclined portion 23 is connected with the upper portion 21 and the lower portion 22 and arranged around the actuating part 213. Consequently, an accommodation space 231 is formed in the inclined portion 23.

In an embodiment, the inclined portion 23 is thinner than the upper portion 21 and the lower portion 22. Preferably but not exclusively, the elastic element 2 is a rubber dome.

Please refer to FIGS. 1, 2A, 2B and 3 again. Each connecting element 3 is connected with the corresponding keycap 1 and the base plate 5. Consequently, the keycap 1 can be moved back and forth relative to the base plate 5 along the direction of the Z axis. The connecting element 3 includes an inner connecting part 31 and an outer connecting part 32. The inner connecting part 31 is pivotally coupled to the inner side of the outer connecting part 32 along a rotation shaft direction R. The inner connecting part 31 includes two inner body parts 311, a first coupling part 312 and a second coupling part 313. The two inner body parts 311 are respectively connected with the first coupling part 312 and the second coupling part 313. The inner connecting part 31 is connected with the corresponding hook structures 51 on the base plate 5 through the first coupling part 312. The inner connecting part 31 is connected with the connection structures 121 on the second surface 12 of the keycap 1 through the second coupling part 313. The outer connecting part 32 includes two outer body parts 321, a third coupling part 322 and a fourth coupling part 323. The two outer body parts 321 are respectively connected with the third coupling part 322 and the fourth coupling part 323. The outer connecting part 32 is connected with the corresponding hook structures 51 on the base plate 5 through the third coupling part 322. The outer connecting part 32 is connected with the corresponding connection structures 121 on the second surface 12 of the keycap 1 through the fourth coupling part 323. Preferably but not exclusively, the connecting element 3 is a scissor-type linkage.

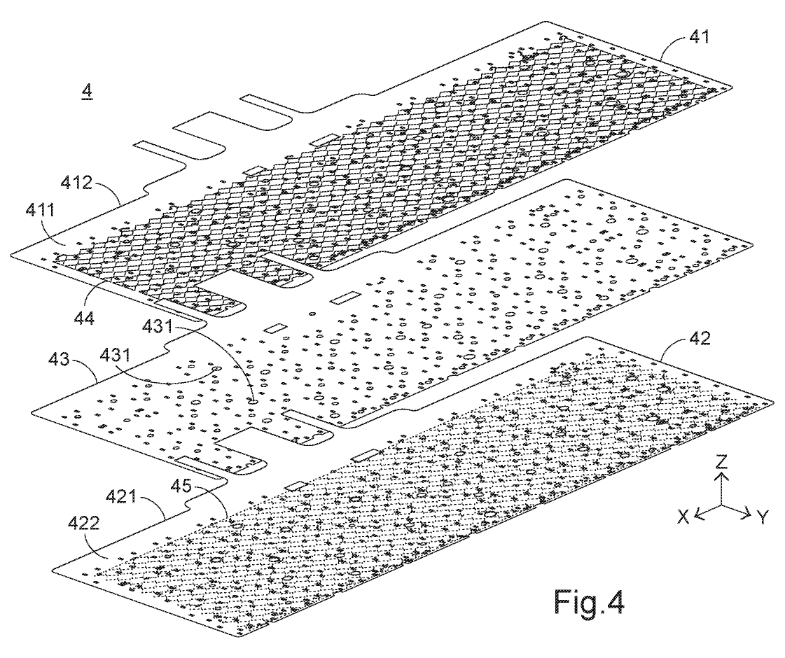

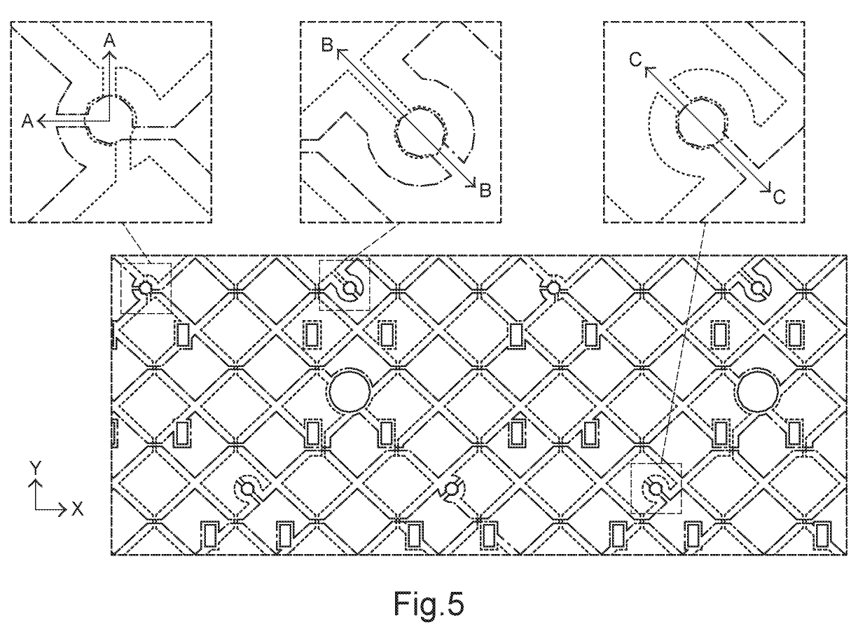

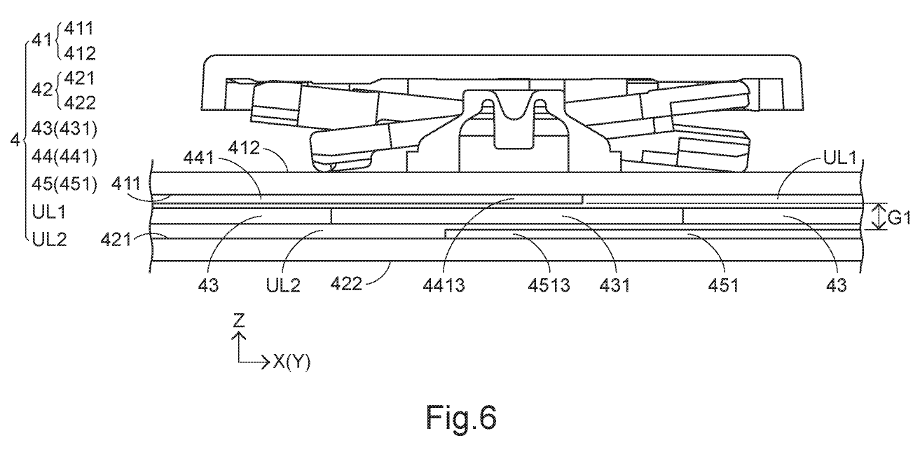

FIG. 4 is a schematic exploded view illustrating the membrane assembly of the touch keyboard according to the embodiment of the present invention. FIG. 5 is a schematic top view illustrating the membrane assembly of the touch keyboard according to the embodiment of the present invention. FIG. 6 is a schematic cross-sectional view of the structure shown in FIG. 5 and taken along the lines A-A, B-B and C-C. The membrane assembly 4 is used to sense the operation gestures, the sliding action and the key switch triggering action.

In an embodiment, the membrane assembly 4 includes a first film layer 41, a second film layer 42, a spacer layer 43, a first capacitor electrode layer 44, a second capacitor electrode layer 45, a first insulation layer UL1 and a second insulation layer UL2.

The first film layer 41 is located over the second film layer 42. The spacer layer 43 is arranged between the first film layer 41 and the second film layer 42. The first film 41 is substantially rectangular in appearance and is used to support the first capacitor electrode layer 44. The first film layer 41 has a first inner surface 411 and a first outer surface 412. The first inner surface 411 and the first outer surface 412 are opposed to each other. The first outer surface 412 is located over the first inner surface 411. That is, the first outer surface 412 faces the plurality of keycaps 1.

The second film layer 42 is substantially rectangular in appearance and is used to support the second capacitor electrode layer 45. The second film layer 42 has a second inner surface 421 and a second outer surface 422. The second inner surface 421 and the second outer surface 422 are opposed to each other. The second inner surface 421 is located over the second outer surface 422. That is, the second inner surface 421 faces the first inner surface 411.

Preferably but not exclusively, the first film layer 41 and the second film layer 42 are made of polyester (e.g., PET).

The spacer layer 43 has a certain thickness. The spacer layer 43 is sandwiched between the first film layer 41 and the second film layer 42. The spacer layer 43 includes a plurality of spacer holes 431. Each spacer hole 431 runs through the spacer layer 43. Due to the arrangement of the spacer holes 431, the first film layer 41 and the second film layer 42 are separated from each other. Preferably but not exclusively, the spacer layer 43 is made of polyester (e.g., PET).

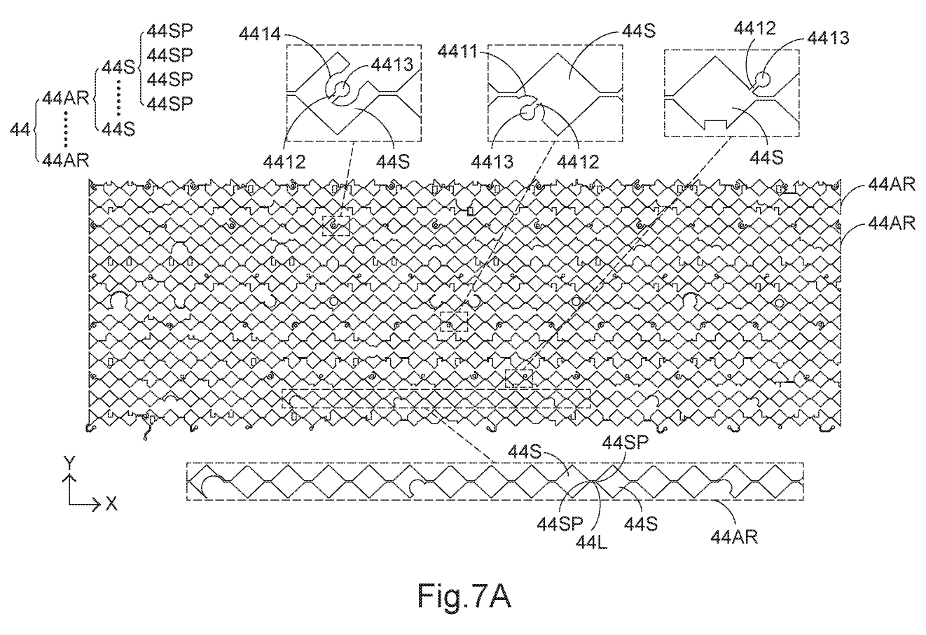

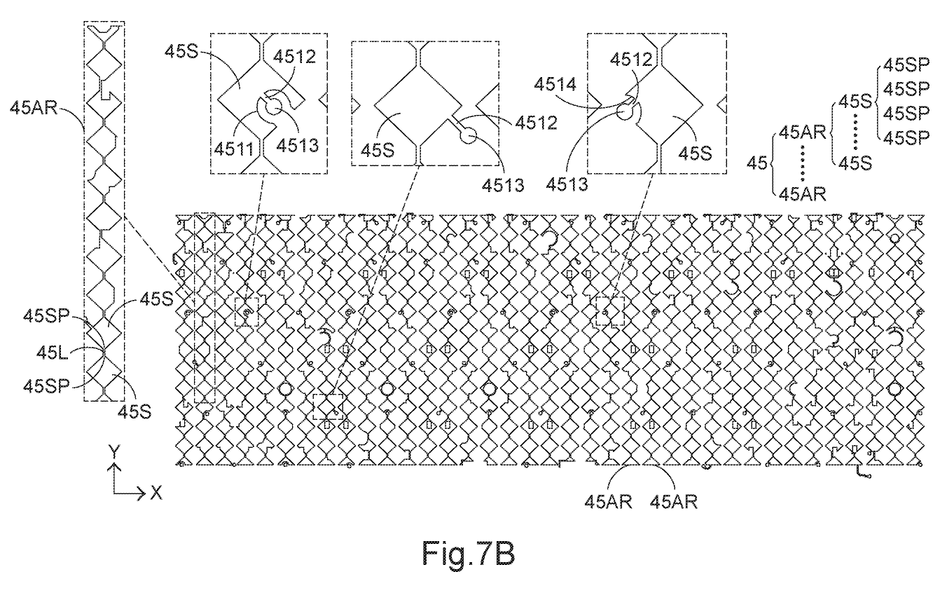

FIG. 7A schematically illustrates a plurality of first electrode arrays in the membrane assembly of the touch keyboard according to the embodiment of the present invention. FIG. 7B schematically illustrates a plurality of second electrode arrays in the membrane assembly of the touch keyboard according to the embodiment of the present invention.

As shown in FIG. 7A, the first capacitor electrode layer 44 includes a plurality of first electrode arrays 44AR. The plurality of first electrode arrays 44AR are extended to cover the underlying region of all the keycaps 1. The plurality of first electrode arrays 44AR are extended linearly along the X-axis direction and are arranged at spacing intervals in the Y-axis direction. In an embodiment, the plurality of first electrode arrays 44AR are disposed on the first inner surface 411 of the first film layer 41. That is, the plurality of first electrode arrays 44AR face the second inner surface 421 of the second film layer 42. Each first electrode array 44AR includes a plurality of first quadrilateral patterns 44S. Each first quadrilateral pattern 44S includes four first vertices 44SP. The first vertex 44SP of one first quadrilateral pattern 44S and the first vertex 44SP of the adjacent first quadrilateral pattern 44S are aligned with each other along the X-axis direction and are connected with each other through a first series connection portion 44L. Preferably but not exclusively, the first quadrilateral patterns 44S are rhombus patterns. Furthermore, a plurality of first switch areas 441 are defined by the plurality of first electrode arrays 44AR. The plurality of first switch areas 441 are respectively located in the plurality of keycap orthographic projection areas 1OP. In an embodiment, the first switch area 441 is approximately close to the center of the corresponding keycap orthographic projection area 1OP. In addition, the first switch area 441 is aligned with the corresponding spacer hole 431 of the spacer layer 43. It is noted that the concepts of the present invention are not limited thereto.

As shown in FIG. 1, the plurality of keycaps 1 in the touch keyboard TK are not all aligned. The plurality of keycaps 1 are staggered in the Y-axis direction. That is, the edges of the plurality of keycaps 1 in the Y-axis direction are not aligned. According to the positions of the keycaps 1, the first switch areas 441 have various possible implementation examples.

In an implementation example, the first switch area 441 includes a first concave portion 4411, a first extension portion 4412 and a first switch portion 4413. The first concave portion 4411 is concavely formed in the first quadrilateral pattern 44S. The first extension portion 4412 is protruded from the first concave portion 4411 and extended in the direction away from the first quadrilateral pattern 44S. The first switch portion 4413 is connected with the first extension portion 4412. Preferably, the first switch portion 4413 is aligned with the center of the keycap orthographic projection area 1OP, and the first switch portion 4413 is aligned with the spacer hole 431 of the spacer layer 43.

In another implementation example, the first switch area 441 includes a first notch portion 4414, a first extension portion 4412 and a first switch portion 4413. The first notch portion 4414 is concaved from an edge of the first quadrilateral pattern 44S toward the interior of the first quadrilateral pattern 44S. The first extension portion 4412 is protruded from the first notch portion 4414 and extended in the direction toward the edge of the first quadrilateral pattern 44S. The first switch portion 4413 is connected with the first extension portion 4412. The first switch portion 4413 is disposed within the first quadrilateral pattern 44S. Preferably, the first switch portion 4413 is aligned with the center of the keycap orthographic projection area 1OP, and the first switch portion 4413 is aligned with the spacer hole 431 of the spacer layer 43.

In another implementation example, the first switch area 441 includes a first extension portion 4412 and a first switch portion 4413. The first extension portion 4412 is protruded from an edge of the first quadrilateral pattern 44S and extended in the direction away from the first quadrilateral pattern 44S. The first switch portion 4413 is connected with the first extension portion 4412. Preferably, the first switch portion 4413 is aligned with the center of the keycap orthographic projection area 1OP, and the first switch portion 4413 is aligned with the spacer hole 431 of the spacer layer 43.

Furthermore, a capacitance is formed between the second capacitor electrode layer 45 and the first capacitor electrode layer 44.

As shown in FIG. 7B, the second capacitor electrode layer 45 includes a plurality of second electrode arrays 45AR. The plurality of second electrode arrays 45AR are extended to cover the underlying region of all the keycaps 1. The plurality of second electrode arrays 45AR are extended linearly along the Y-axis direction and are arranged at spacing intervals in the X-axis direction. In an embodiment, the plurality of second electrode arrays 45AR are disposed on the second inner surface 421 of the second film layer 42. That is, the plurality of second electrode arrays 45AR face the first inner surface 411 of the first film layer 41. Each second electrode array 45AR includes a plurality of second quadrilateral patterns 45S. Each second quadrilateral pattern 45S includes four second vertices 45SP. The second vertex 45SP of one second quadrilateral pattern 45S and the second vertex 45SP of the adjacent second quadrilateral pattern 45S are aligned with each other along the Y-axis direction and are connected with each other through a second series connection portion 45L. Preferably but not exclusively, the second quadrilateral patterns 45S are rhombus patterns. Furthermore, a plurality of second switch areas 451 are defined by the plurality of second electrode arrays 45AR. The plurality of second switch areas 451 are respectively located in the plurality of keycap orthographic projection areas 1OP. In an embodiment, the second switch area 451 is approximately close to the center of the corresponding keycap orthographic projection area 1OP. In addition, the second switch area 451 is aligned with the corresponding spacer hole 431 of the spacer layer 43. The second switch region 451 and the first switch region 441 are at least partially overlapped with each other in the Z-axis direction. That is, the second switch region 451 and the first switch region 441 are at least partially overlapped with each other in the vertical direction. It is noted that the concepts of the present invention are not limited thereto.

As shown in FIG. 1, the plurality of keycaps 1 in the touch keyboard TK are not all aligned. The plurality of keycaps 1 are staggered in the Y-axis direction. That is, the edges of the plurality of keycaps 1 in the Y-axis direction are not aligned. According to the positions of the keycaps 1, the second switch areas 451 have various possible implementation examples.

In an implementation example, the second switch area 451 includes a second concave portion 4511, a second extension portion 4512 and a second switch portion 4513. The second concave portion 4511 is concavely formed in the second quadrilateral pattern 45S. The second extension portion 4512 is protruded from the second concave portion 4511 and extended in the direction away from the second quadrilateral pattern 45S. The second switch portion 4513 is connected with the second extension portion 4512. Preferably, the second switch portion 4513 is aligned with the center of the keycap orthographic projection area 1OP, and the second switch portion 4513 is aligned with the spacer hole 431 of the spacer layer 43. The second switch portion 4513 and the first switch portion 4413 are overlapped with each other in the Z-axis direction. That is, the second switch portion 4513 and the first switch portion 4413 are overlapped with each other in the vertical direction. In addition, the first switch portion 4413 and the second switch portion 4513 are separated from each other by a first gap G1 through the spacer hole 431 of the spacer layer 43.

In another implementation example, the second switch area 451 includes a second notch portion 4514, a second extension portion 4512 and a second switch portion 4513. The second notch portion 4514 is concaved from an edge of the second quadrilateral pattern 45S toward the interior of the second quadrilateral pattern 45S. The second extension portion 4512 is protruded from the second notch portion 4514 and extended in the direction toward the edge of the second quadrilateral pattern 45S. The second switch portion 4513 is connected with the second extension portion 4512. The second switch portion 4513 is disposed within the second quadrilateral pattern 45S. Preferably, the second switch portion 4513 is aligned with the center of the keycap orthographic projection area 1OP, and the second switch portion 4513 is aligned with the spacer hole 431 of the spacer layer 43. The second switch portion 4513 and the first switch portion 4413 are overlapped with each other in the Z-axis direction. That is, the second switch portion 4513 and the first switch portion 4413 are overlapped with each other in the vertical direction. In addition, the first switch portion 4413 and the second switch portion 4513 are separated from each other by a first gap G1 through the spacer hole 431 of the spacer layer 43.

In another implementation example, the second switch area 451 includes a second extension portion 4512 and a second switch portion 4513. The second extension portion 4512 is protruded from an edge of the second quadrilateral pattern 45S and extended in the direction away from the second quadrilateral pattern 45S. The second switch portion 4513 is connected with the second extension portion 4512. Preferably, the second switch portion 4513 is aligned with the center of the keycap orthographic projection area 1OP, and the second switch portion 4513 is aligned with the spacer hole 431 of the spacer layer 43. The second switch portion 4513 and the first switch portion 4413 are overlapped with each other in the Z-axis direction. That is, the second switch portion 4513 and the first switch portion 4413 are overlapped with each other in the vertical direction. In addition, the first switch portion 4413 and the second switch portion 4513 are separated from each other by a first gap G1 through the spacer hole 431 of the spacer layer 43.

In an embodiment, the first capacitor electrode layer 44 includes a plurality of receiving electrodes (Rx) or a plurality of transmitting electrodes (Tx), and the second capacitor electrode layer 45 includes electrodes corresponding to the first capacitor electrode layer 44. For example, if the first capacitor electrode layer 44 includes a plurality of receiving electrodes, the second capacitor electrode layer 45 includes a plurality of transmitting electrodes. Whereas, if the first capacitor electrode layer 44 includes a plurality of transmitting electrodes, the second capacitor electrode layer 45 includes a plurality of receiving electrodes.

The first insulation layer UL1 is used to insulate the first capacitor electrode layer 44. The first insulation layer UL1 covers the surface of the first capacitor electrode layer 44. The first insulation layer UL1 can also be extended to cover the entire first inner surface 411 of the first film layer 41. Preferably but not exclusively, the first insulation layer UL1 is a UV (ultraviolet) layer. The second insulation layer UL2 is used to insulate the second capacitor electrode layer 45. The second insulation layer UL2 covers the surface of the second capacitor electrode layer 45. The second insulation layer UL2 can also be extended to cover the entire second inner surface 421 of the second film layer 42. Preferably but not exclusively, the second insulation layer UL2 is a UV (ultraviolet) layer.

Please refer to FIGS. 2A, 2B and 3. The base plate 5 is used to support the touch keyboard TK. The base plate 5 is a rectangular plate in appearance. Preferably but not exclusively, the base plate 5 is made of plastic material, metallic material or any other appropriate hard material. The base plate 5 is located under the membrane assembly 4. In an embodiment, the base plate 5 and the second outer surface 422 of the second film layer 42 of the membrane assembly 4 are attached on each other. The base plate 5 includes a plurality of hook structures 51. The hook structures 51 are protruded from the plate body of the base plate 5 and extended along the positive direction of the Z axis. The hook structures 51 are penetrated through the avoidance holes H of the capacitive membrane assembly 4. In an embodiment, the hook structures 51 are formed by using a stamping process. It is noted that the method of forming the hook structures 51 is not restricted.

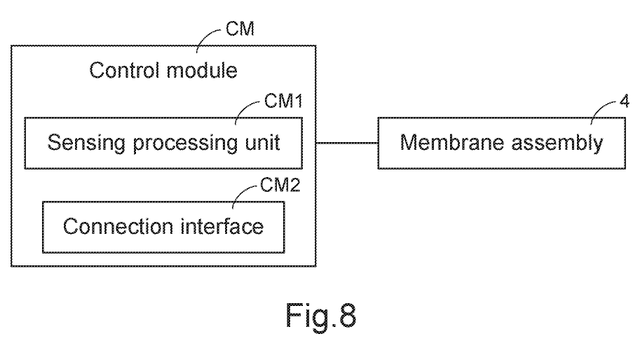

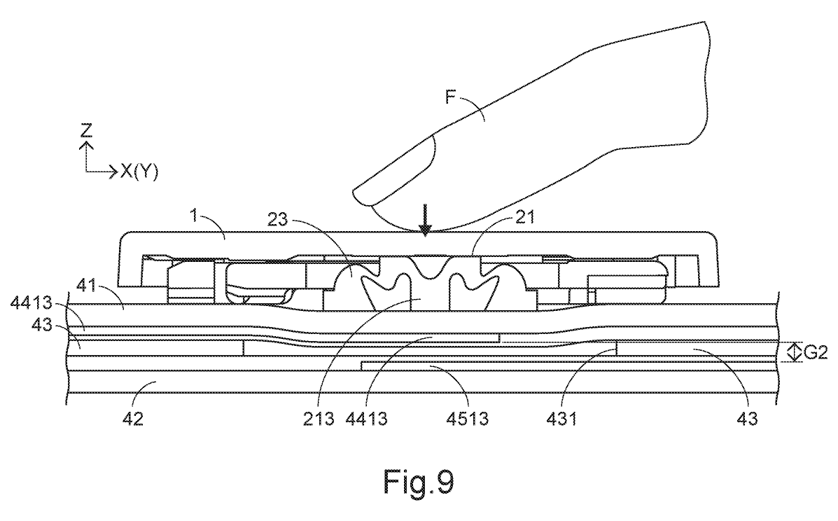

FIG. 8 is a schematic functional block diagram illustrating a control mechanism of the touch keyboard according to the embodiment of the present invention. The control module CM includes a sensing processing unit CM1 and a connection interface CM2. The membrane assembly 4 is connected with the sensing processing unit CM1. The sensing processing unit CM1 is used to sense the capacitance value of the capacitor that is formed by the capacitor electrodes of the membrane assembly 4. In an embodiment, at least two sets of capacitance threshold value intervals corresponding to a pressing operation or a sliding gesture operation of the user’s finger F (see FIG. 9) are preset. The control module CM outputs the sensing result of the sensing processing unit CM1 through the connection interface CM2. For example, the control module CM outputs text/number input and the touch position corresponding to the key structure.

FIG. 9 is a schematic cross-sectional view illustrating a portion of the touch keyboard when the touch keyboard is pressed by the user. For example, when the keycap 1 is pressed by a charged object (e.g., the user’s finger F), the keycap 1 is moved along the negative direction of the Z axis. That is, the keycap 1 is moved downwardly. As the keycap 1 is moved downwardly to press the upper portion 21 of the elastic element 2, the inclined portion 23 of the elastic element 2 is subjected to deformation and the membrane assembly 4 is pushed by the actuating part 213. Consequently, the first switch portion 4413 is moved downwardly toward the corresponding second switch portion 4513 through the spacer hole 431 of the spacer layer 43. Since the distance between the first switch portion 4413 and the second switch portion 4513 is decreased from the first gap G1 to the second gap G2, the capacitance value of the capacitor between the first switch portion 4413 and the second switch portion 4513 is subjected to a change.

The sensing processing unit CM1 can determine whether any key is pressed according to the result of detecting the change of the capacitance value of the capacitor. In addition, the sensing result of the sensing processing unit CM1 is outputted from the control module CM through the connection interface CM2. In an embodiment, the second gap G2 is greater than zero. When the key signal is outputted, the first switch part 4413 and the second switch part 4513 will not be contacted with each other. Preferably but not exclusively, the first gap G1 is 0.1 mm, and the second gap G2 is 0.01 mm. The size of the first gap G1 and the size of the second gap G2 is 0.01 mm may be varied according to the practical requirements.

When the user’s finger F slides on the touch keyboard TK but does not press any keycap 1, a gesture operation is performed on the touch keyboard TK. The capacitance value of the capacitor between the first electrode layer 44 and the second electrode layer 45 is also subjected to a change. According to the change of the capacitance value, the sensing processing unit CM1 can determine whether the user performs any gesture operation on the touch keyboard TK. The technologies of judging the gesture according to the capacitance change of the touch keyboard TK are known to those skilled in the art, and not redundantly described herein.

From the above descriptions, the touch keyboard of the present invention is advantageous over the conventional touch keyboard. Firstly, the touch keyboard of the present invention has the key input function, the cursor sliding function and the gesture input function. By using the touch keyboard of the present invention, the computing device does not need to be connected with too many input devices (e.g., touchpads or mice). Secondly, the first capacitor electrode layer and the second capacitor electrode layer of the membrane assembly are extended to all keycap orthographic projection areas. Thirdly, when the keycap is pressed to generate a key signal, the first switch portion and the second switch portion are not in contact with each other. Since the wear and tear problems are effectively solved, the product life can be extended.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A touch keyboard, comprising:
a plurality of keycaps; and
a membrane assembly located under the plurality of keycaps, wherein the plurality of keycaps respectively have respective keycap orthographic projection areas on the membrane assembly, and the membrane assembly comprises a first capacitor electrode layer, a second capacitor electrode layer and a spacer layer,
wherein the first capacitor electrode layer comprises a plurality of first switch areas, and the plurality of first switch areas are included in the respective keycap orthographic projection areas,
wherein the second capacitor electrode layer comprises a plurality of second switch areas, and the plurality of second switch areas are included in the respective keycap orthographic projection areas, wherein a capacitor is formed between the first capacitor electrode layer and the second capacitor electrode layer, and there is at least an overlap region between each first switch area and the corresponding second switch area in a vertical direction,
wherein the spacer layer comprises a plurality of spacer holes, and each spacer hole is aligned with the overlap region between the corresponding first switch area and the corresponding second switch area in the vertical direction, so that the corresponding first switch area and the corresponding second switch area are separated from each other by a first gap through the spacer hole.

2. The touch keyboard according to claim 1, wherein the membrane assembly further comprises a first film layer and a second film layer, and the spacer layer is sandwiched between the first film layer and the second film layer.

3. The touch keyboard according to claim 2, wherein the first film layer has a first inner surface and a first outer surface, and the second film layer has a second inner surface and a second outer surface, wherein the first inner surface and the first outer surface are opposed to each other, the second inner surface and the second outer surface are opposed to each other, and the first inner surface faces the second inner surface.

4. The touch keyboard according to claim 3, wherein the first capacitor electrode layer is disposed on the first inner surface, and the second capacitor electrode layer is disposed on the second inner surface.

5. The touch keyboard according to claim 1, wherein the first capacitor electrode layer comprises a plurality of first electrode arrays, and the second capacitor electrode layer comprises a plurality of second electrode arrays, wherein the plurality of first electrode arrays are extended along a first direction and arranged at spacing intervals in a second direction, and the plurality of second electrode arrays are extended along the second direction and arranged at spacing intervals in the first direction, wherein the first direction and the second direction are perpendicular to each other.

6. The touch keyboard according to claim 1, wherein the membrane assembly is further connected with a control module, wherein when the overlap region between the corresponding first switch area and the corresponding second switch area of the membrane assembly is pressed, the corresponding first switch area and the corresponding second switch area are closer to each other and separated from each other by a second gap through the spacer hole, so that a capacitance value of the capacitor between the corresponding first switch area and the corresponding second switch is subjected to a change, wherein the control module generates a key signal according to the change of the capacitance value, and the second gap is greater than zero.

7. The touch keyboard according to claim 6, wherein the first gap is 0.1 mm, and the second gap is 0.01 mm.

8. The touch keyboard according to claim 1, wherein each of the first switch area and the second switch area comprises a switch portion and further comprises an extension portion, a concave portion, a notch portion, or a combination thereof.

9. The touch keyboard according to claim 4, wherein the membrane assembly further comprises a first insulation layer and a second insulation layer, wherein the first insulation layer covers a surface of the first capacitor electrode layer, and the second insulation layer covers a surface of the second capacitor electrode layer.

10. The touch keyboard according to claim 9, wherein the first insulation layer is extended to cover the first inner surface of the first film layer, and the second insulation layer is extended to cover the second inner surface of the second film layer.

11. The touch keyboard according to claim 1, wherein the touch keyboard further comprises:
a plurality of connecting elements;
a base plate; and
a plurality of elastic elements,
wherein the plurality of connecting elements are pivotally coupled to the respective keycaps and the base plate, and the plurality of keycaps are movable relative to the base plate through the plurality of connecting elements,
wherein the base plate is located under the membrane assembly, the plurality of elastic elements are arranged between the respective keycaps and the membrane assembly, and each of the keycaps is permitted to be returned to an original position in response to an elastic restoring force of the corresponding elastic element.

12. A membrane assembly, comprising:
a first capacitor electrode layer comprising a plurality of first switch areas;
a second capacitor electrode layer comprising a plurality of second switch areas, wherein a capacitor is formed between the first capacitor electrode layer and the second capacitor electrode layer, and there is at least an overlap region between each first switch area and the corresponding second switch area in a vertical direction; and
a spacer layer comprising a plurality of spacer holes, wherein each spacer hole is aligned with the overlap region between the corresponding first switch area and the corresponding second switch area in the vertical direction, so that the corresponding first switch area and the corresponding second switch area are separated from each other by a first gap through the spacer hole.

13. The membrane assembly according to claim 12, wherein the membrane assembly further comprises a first film layer and a second film layer, and the spacer layer is sandwiched between the first film layer and the second film layer.

14. The membrane assembly according to claim 13, wherein the first film layer has a first inner surface and a first outer surface, and the second film layer has a second inner surface and a second outer surface, wherein the first inner surface and the first outer surface are opposed to each other, the second inner surface and the second outer surface are opposed to each other, and the first inner surface faces the second inner surface.

15. The membrane assembly according to claim 14, wherein the first capacitor electrode layer is disposed on the first inner surface, and the second capacitor electrode layer is disposed on the second inner surface.

16. The membrane assembly according to claim 12, wherein the first capacitor electrode layer comprises a plurality of first electrode arrays, and the second capacitor electrode layer comprises a plurality of second electrode arrays, wherein the plurality of first electrode arrays are extended along a first direction and arranged at spacing intervals in a second direction, and the plurality of second electrode arrays are extended along the second direction and arranged at spacing intervals in the first direction, wherein the first direction and the second direction are perpendicular to each other.

17. The membrane assembly according to claim 12, wherein the membrane assembly is further connected with a control module, wherein when the overlap region between the corresponding first switch area and the corresponding second switch area of the membrane assembly is pressed, the corresponding first switch area and the corresponding second switch area are closer to each other and separated from each other by a second gap through the spacer hole, so that a capacitance value of the capacitor between the corresponding first switch area and the corresponding second switch is subjected to a change, wherein the control module generates a key signal according to the change of the capacitance value, and the second gap is greater than zero.

18. The membrane assembly according to claim 17, wherein the first gap is 0.1 mm, and the second gap is 0.01 mm.

19. The membrane assembly according to claim 12, wherein each of the first switch area and the second switch area comprises a switch portion and further comprises an extension portion, a concave portion, a notch portion, or a combination thereof.

20. The membrane assembly according to claim 15, wherein the membrane assembly further comprises a first insulation layer and a second insulation layer, wherein the first insulation layer covers a surface of the first capacitor electrode layer, and the second insulation layer covers a surface of the second capacitor electrode layer.

21. The membrane assembly according to claim 20, wherein the first insulation layer is extended to cover the first inner surface of the first film layer, and the second insulation layer is extended to cover the second inner surface of the second film layer.
